(19) United States
(12) Patent Application Publication
(10) Pub. No.: US 2026/0068140 A1
(43) Pub. Date: Mar. 5, 2026

(54) SEMICONDUCTOR DEVICES AND MANUFACTURING METHOD THEREOF

(71) Applicant: Samsung Electronics Co., Ltd., Suwon-si (KR)

(72) Inventors: Jongin Kang, Suwon-si (KR); Ji-Eun Lee, Suwon-si (KR); Hoin Lee, Suwon-si (KR)

(21) Appl. No.: 19/036,280

(22) Filed: Jan. 24, 2025

(30) Foreign Application Priority Data
Aug. 29, 2024 (KR) 10-2024-0117130

(51) Int. Cl. H10B 12/00

(52) U.S. Cl. CPC H10B 12/485; H10B 12/0335; H10B 12/315; H10B 12/34

(57) ABSTRACT

A semiconductor device includes a substrate including an active region, a word line on the active region and extending in the first direction that is parallel to the substrate, a capping insulating layer on the word line, a bit line overlapping the active region in the first direction and extending in a second direction intersecting the first direction, a buried contact electrically connected to the active region, a direct contact electrically connecting the active region and the bit line, and a landing pad electrically connected to the buried contact. The capping insulating layer includes a first capping insulating layer and a second capping insulating layer having different widths in the second direction, the second capping insulating layer is on the first capping insulating layer, and the buried contact is on side surfaces of the second capping insulating layer.

### CROSS-REFERENCE TO RELATED APPLICATION

This application claims priority to and the benefit of Korean Patent Application No. 10-2024-0117130 filed in the Korean Intellectual Property Office on Aug. 29, 2024, the entire contents of which are incorporated herein by reference.

### TECHNICAL FIELD

The present disclosure relates to semiconductor devices and a manufacturing method thereof.

### BACKGROUND

As an integration degree of semiconductor devices, e.g., semiconductor memory devices, increases, circuits are becoming smaller, and accordingly, manufacturing processes are becoming increasingly complicated and difficult. Particularly, design hurdles such as deterioration of contact characteristics between fine patterns or processing errors generated when stacking predetermined layers in a fine region are increasing.

### SUMMARY

The present disclosure attempts to provide a semiconductor device for increasing reliability and productivity and a manufacturing method thereof.

However, technical hurdles to be solved by embodiments of the present disclosure may not be limited to the above-described task, and may include hurdles within a range of technical scopes included in the present disclosure.

An embodiment of the present disclosure provides a semiconductor device including a substrate including an active region, a word line on the active region and extending in the first direction that is parallel to the substrate, a capping insulating layer on the word line, a bit line overlapping the active region in the first direction and extending in a second direction intersecting the first direction, a buried contact electrically connected to the active region, a direct contact electrically connecting the active region and the bit line, and a landing pad electrically connected to the buried contact. The capping insulating layer includes a first capping insulating layer and a second capping insulating layer having different widths in the second direction, the second capping insulating layer is on the first capping insulating layer, and the buried contact is on side surfaces of the second capping insulating layer.

A method for manufacturing a semiconductor device may include forming an element separating layer that extends into an active region that is on a substrate, forming a word line overlapping the active region in a first direction parallel to the substrate and extending in the first direction parallel to the substrate, forming a capping insulating layer on the word line, forming a bit line overlapping the active region in the first direction and extending in a second direction intersecting the first direction, forming a buried contact electrically connected to the active region, forming a direct contact electrically connecting the active region and the bit line, and forming a landing pad electrically connected to the buried contact. The forming of the capping insulating layer includes forming a first capping insulating layer on the word line, where the first capping insulating layer has a first width, forming a plurality of dummy spacer layers on the first capping insulating layer, forming a second capping insulating layer between ones of the plurality of dummy spacer layers, the second capping insulating layer having a second width in the second direction, and removing the dummy spacer layers. The forming of a buried contact includes forming a portion of the buried contact on lateral surfaces of the second capping insulating layer in the second direction. The forming of a capping insulating layer may include forming a first capping insulating layer having a first width in the word line, forming dummy spacer layers on the first capping insulating layer, forming a second capping insulating layer having a second width between the dummy spacer layers, and removing the dummy spacer layers. The forming of the buried contact may include forming a portion of the buried contact on both lateral surfaces of the second capping insulating layer facing each other in the second direction.

According to the embodiments, the semiconductor device with increased reliability and productivity and the manufacturing method thereof may be provided.

The effects of the present disclosure are not limited to the above-described effects, and may be expanded in various ways in the range of the ideas and the areas of the present disclosure.

### BRIEF DESCRIPTION OF THE DRAWINGS

FIG. 1 shows a partial top plan view of a semiconductor device according to embodiments of the present disclosure.

FIG. 2 shows a cross-sectional view taken along a line I-I′ of FIG. 1.

FIG. 3 shows a cross-sectional view taken along a line II-II′ of FIG. 1.

FIG. 4 shows a cross-sectional view taken along a line III-III′ of FIG. 1.

FIG. 5 shows an enlarged view of an RG region of FIG. 2.

FIG. 6 shows a plan view of a process for manufacturing a semiconductor device according to embodiments of the present disclosure.

FIG. 7 shows a cross-sectional view taken along a line I-I′ of a process for manufacturing the semiconductor device of FIG. 6.

FIG. 8 shows a cross-sectional view taken along a line III-III′ of a process for manufacturing the semiconductor device of FIG. 6.

FIG. 9 to FIG. 14 show cross-sectional views of a semiconductor device of FIG. 7 in processing order.

FIG. 15, FIG. 18, FIG. 21, and FIG. 24 show plan views in a process for manufacturing a semiconductor device according to embodiments of the present disclosure.

FIG. 16, FIG. 19, FIG. 22, and FIG. 25 show cross-sectional views of a semiconductor device taken along a line I-I′ in processing order in a process for manufacturing a semiconductor device according to embodiments of the present disclosure.

FIG. 17, FIG. 20, and FIG. 23 show cross-sectional views of a semiconductor device taken along a line III-III′ in processing order in a process for manufacturing a semiconductor device according to embodiments of the present disclosure.

### DETAILED DESCRIPTION

The embodiments will be described more fully hereinafter with reference to the accompanying drawings, in which embodiments are shown. As those skilled in the art would realize, the described embodiments may be modified in various different ways, all without departing from the spirit or scope of this disclosure.

Parts that are irrelevant to the description will be omitted to clearly describe this disclosure, and the same elements will be designated by the same reference numerals throughout the specification.

The accompanying drawings are provided only in order to allow embodiments disclosed in the present specification to be easily understood and are not to be interpreted as limiting the spirit disclosed in the present specification, and it is to be understood that this disclosure includes all modifications, equivalents, and substitutions without departing from the scope and spirit of this disclosure.

The size and thickness of each configuration shown in the drawings are arbitrarily shown for better understanding and ease of description, but the present disclosure is not limited thereto. In the drawings, the thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on, above, or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements. The term “and/or” includes any and all combinations of one or more of the associated listed items.

The phrase “in a plan view” means viewing an object portion from the top, and the phrase “in a cross-sectional view” means viewing a cross-section of which the object portion is perpendicularly cut from the side.

When it is described that a part is “connected” to another part, the part may be “directly connected” to the other element, may be “connected” to the other part through a third part, or may be connected to the other part physically or electrically, and they may be referred to by different titles depending on positions or functions, but respective portions that are substantially integrated into one body may be connected to each other.

Various embodiments and variations will now be described with reference to accompanying drawings.

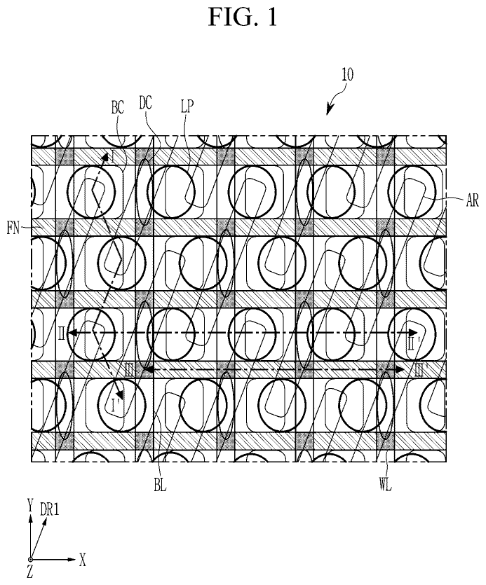

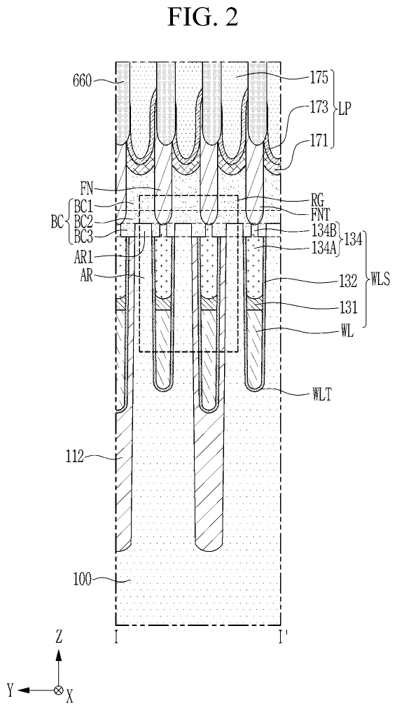

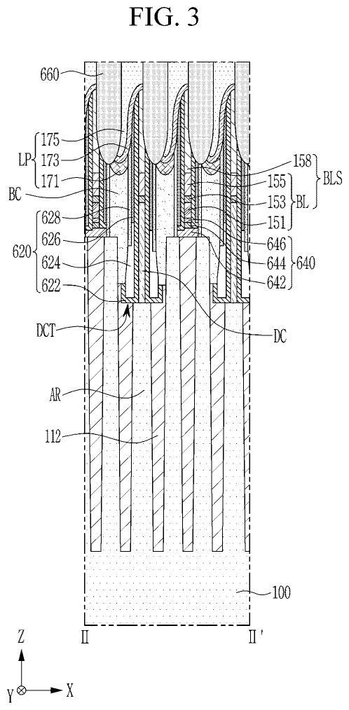

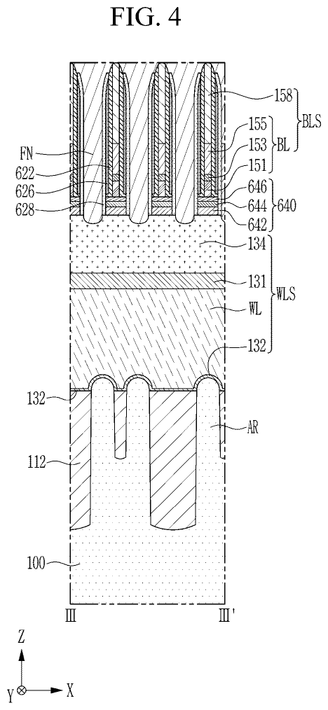

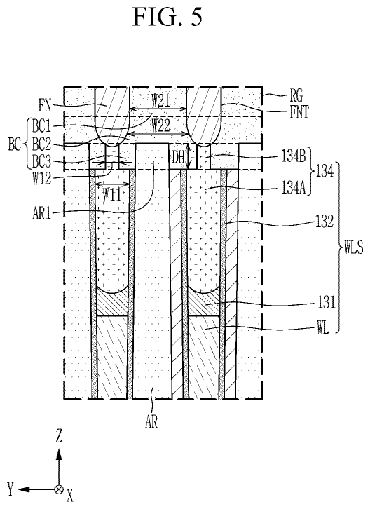

A semiconductor device according to an embodiment will now be described with reference to FIG. 1 to FIG. 5. FIG. 1 shows a partial top plan view of a semiconductor device according to an embodiment, FIG. 2 shows a cross-sectional view with respect to a line I-I′ of FIG. 1, FIG. 3 shows a cross-sectional view with respect to a line II-II′ of FIG. 1, FIG. 4 shows a cross-sectional view with respect to a line III-III′ of FIG. 1, and FIG. 5 shows an enlarged view of an RG region of FIG. 2.

Referring to FIG. 1 to FIG. 5, the semiconductor device 10 according to an embodiment may include an active region AR, a word line WL crossing the active region AR and overlapping the same, a bit line BL crossing the active region AR in a different direction from the word line WL and overlapping the same, a direct contact DC connecting the active region AR and the bit line BL, a buried contact BC connecting the active region AR and a landing pad LP, and a fence pattern FN disposed between bit lines BL.

The word line WL may extend in a first direction X and may cross the active region AR. The word line WL may overlap the active region AR and may function as a gate electrode. One word line WL may overlap adjacent active regions AR in the first direction X.

The semiconductor device 10 may include word lines WL. The word lines WL may extend in parallel to each other in the first direction X and may be spaced apart from each other in a second direction Y.

The semiconductor device 10 may include the bit lines BL. The bit lines BL may extend in parallel to each other in the second direction Y and may be spaced apart from each other in the first direction X.

The active region AR may be defined by an element separating layer 112 disposed in the substrate 100. The active regions AR may be disposed in the substrate 100, and may be separated from each other by the element separating layer 112. The element separating layer 112 may be disposed on both sides of the active region AR.

The substrate 100 may include a semiconductor material. For example, the substrate 100 may include a group IV semiconductor, a group III-V compound semiconductor, and/or a group II-VI compound semiconductor. For example, the substrate 100 may include a semiconductor such as Si or Ge, or a compound semiconductor such as SiGe, SiC, GaAs, InAs, or InP. The substrate 100 may be a silicon substrate or a silicon-on-insulator (SOI). The substrate 100 may include silicon germanium, silicon germanium on insulator (SGOI), indium antimonide, lead telluride compound, indium arsenic, indium phosphide, gallium arsenic, and/or gallium antimonide, but is not limited thereto. However, the material of the substrate 100 is not limited thereto and may be changed in many ways.

The substrate 100 may have an upper surface in parallel to the first direction X and the second direction Y, and may have a thickness in parallel to a third direction Z substantially perpendicular to the first direction X and the second direction Y.

The substrate 100 may include a cell array region and a peripheral circuit region.

Memory cells are formed in the cell array region, and the active regions AR may be disposed in the cell array region. The peripheral circuit region may surround the cell array region, and elements for driving the memory cells may be disposed therein. FIG. 1 to FIG. 4 show the cell array region and omit the peripheral circuit region, for ease of description.

The element separating layer 112 may have a shallow trench isolation (STI) structure having an excellent element separating characteristic. The element separating layer 112 may be made of silicon oxide, silicon nitride, or combinations thereof. However, the material of the element separating layer 112 is not limited thereto, and may be changed in many ways.

The element separating layer 112 may be a single layer or a multilayer. The element separating layer 112 may be made of a single material or may include at least two types of insulating materials.

The active region AR may have a bar shape extending in a fourth direction DR1 oblique to the first direction X and the second direction Y. The fourth direction DR1 may be disposed in parallel to an upper surface of the substrate 100 and on a same plane as the first direction X and the second direction Y. The fourth direction DR1 may respectively form an acute angle with respect to the first direction X and the second direction Y. The active regions AR may extend in parallel to each other.

The active regions AR may be spaced apart from each other at predetermined intervals in the fourth direction DR1 and the first direction X. A center of one active region AR may be disposed near an end of another active region AR in the first direction X. A first end of one active region AR may be disposed near a second end of another active region AR in the first direction X. However, the shape or arrangement of the active region AR is not limited thereto, and may be changed in many ways.

According to an embodiment, each of the active regions AR may cross two word lines WL and may be connected to one bit line BL. The active region AR may be divided into three portions with the two word lines WL as a boundary, the center portion may be connected to the bit line BL through a direct contact DC, and both the end portions may be connected to a capacitor (not shown) through the buried contact BC and the landing pad LP.

The direct contact DC may overlap the bit line BL and the active region AR and may contact them, and may be disposed in the center of the active region AR. Both the end portions of an active region AR may be overlapped by a buried contact BC. The buried contact BC may physically and/or electrically connect the end portions of active regions AR, and may be disposed in a space partitioned by the fence pattern FN extending in the horizontal direction and the bit line BL extending in the perpendicular direction. The fence pattern FN may overlap the word line WL.

The landing pad LP may overlap the buried contact BC and may contact the same, and may be disposed in the space between the adjacent word line WL. The landing pad LP may contact an electrode of the capacitor (not shown). The landing pad LP may be used because the buried contact BC has a small area according to an arranged structure, and the landing pad LP may increase the substantial contact area of the buried contact BC and the capacitor electrode to reduce contact resistance. However, embodiments are not limited thereto, and the landing pad LP may be omitted.

The above-described word line WL, the bit line BL, the active region AR, the direct contact DC, the buried contact BC, and the landing pad LP may be realized or implemented on the substrate 100 as various types structural elements.

A word line trench WLT may be formed on the substrate 100, and a word line structure WLS may be disposed in the word line trench WLT. That is, the word line structure WLS may be buried in the substrate 100. A portion of the word line trench WLT may be disposed in the active region AR, and another portion thereof may be disposed on the element separating layer 112.

As shown in FIG. 2, bottom surfaces of the word line trenches WLT may be disposed on different levels in the third direction Z. The bottom surface of the word line trench WLT disposed on the substrate 100 may be disposed at a higher level than the bottom surface of the word line trench WLT disposed on the element separating layer 112.

That is, regarding the word line trenches WLT, as the element separating layer 112 and the substrate 100 are etched by individual etching processes, an etching depth of the element separating layer 112 may be different from an etching depth of the substrate 100. By this, the bottom surfaces of the word line trenches WLT may be disposed at different levels. However, the method for etching the element separating layer 112 and the substrate 100 is not limited thereto. In some embodiments, the element separating layer 112 and the substrate 100 may be simultaneously etched. As described, when simultaneously etching the element separating layer 112 and the substrate 100, the element separating layer 112 and the substrate 100 have different materials, and the element separating layer 112 and the substrate 100 may have different etching depths by the difference of etching rates of the element separating layer 112 and the substrate 100.

The level may represent the height in the third direction Z perpendicular to the upper surface of the substrate 100. That is, being disposed on the same level may represent that the heights in the third direction Z perpendicular to the upper surface of the substrate 100 are equal to each other, and being disposed on the lower or higher level may represent that the height in the third direction Z perpendicular to the upper surface of the substrate 100 is low or high respectively.

The word line structure WLS may include a gate insulating layer 132, a word line WL disposed on the gate insulating layer 132, and a capping conductive layer 131 and a capping insulating layer 134 disposed on the word line WL. However, the position, shape, and structure of the word line structure WLS is not limited thereto, and may be changed in many ways.

The gate insulating layer 132 may be disposed in the word line trench WLT. The gate insulating layer 132 may be conformally formed on an internal lateral surface of the word line trench WLT.

The gate insulating layer 132 may, for example, include at least one of silicon oxide, silicon nitride, silicon oxynitride, or a high dielectric constant material with a greater dielectric constant than the silicon oxide. The high dielectric constant material may, for example, include at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and/or combinations thereof. However, embodiments are not limited thereto.

The word line WL may be disposed on the gate insulating layer 132. A lateral surface and a bottom surface of the word line WL may be surrounded by the gate insulating layer 132. The gate insulating layer 132 may be disposed between the word line WL and the active region AR. Therefore, the word line WL may not directly contact the active region AR.

The upper surface of the word line WL may be disposed at a lower level than the upper surface of the substrate 100. As shown in FIG. 4, the bottom surface of the word line WL may have protrusions and depressions in a cross-sectional view, and saddle-fin transistors (FET) may be formed in the active regions AR

The word line WL and the capping conductive layer 131 may be a single layer or a multilayer. The word line WL may, for example, include at least one of metal, metal alloy, conductive metal nitride, conductive metal carbonitride, conductive metal carbide, metal silicide, semiconductor material containing impurities, conductive metal oxynitride, and/or conductive metal oxide. The word line WL may, for example, include at least one of TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, and/or combinations thereof.

The capping insulating layer 134 may fill an upper space of the word line trench WLT. The capping insulating layer 134 may cover, overlap, or be on the upper surface of the word line WL. The bottom surface of the capping insulating layer 134 may contact the word line WL.

The capping insulating layer 134 may include a first capping insulating layer 134A and a second capping insulating layer 134B having different widths in the second direction Y.

A lateral surface of the first capping insulating layer 134A may be covered by or overlapped by the gate insulating layer 132.

Referring to FIG. 5, a width W11 of the first capping insulating layer 134A may be greater than a width W12 of the second capping insulating layer 134B.

The active region AR disposed between the adjacent word line structures WLS and contacting the buried contact BC may include an upper end portion AR1 protruding further than the first capping insulating layer 134A in the third direction Z.

Third portions BC3 of the buried contacts BC may be disposed on both lateral surfaces of the second capping insulating layer 134B facing each other in the second direction Y.

The level of the top surface of the upper end portion AR1 of the active region AR may be higher than the level of the first capping insulating layer 134A of the capping insulating layer 134 by a level difference DH in the third direction Z, and the level of the top surface of the upper end portion AR1 may be substantially equal to or greater than the level of the second capping insulating layer 134B. Therefore, a lateral surface of the second capping insulating layer 134B may be spaced from a lateral surface of the upper end portion AR1 of the active region AR and may face each other in the second direction Y. The third portion BC3 of the buried contact BC may be disposed between the lateral surface of the second capping insulating layer 134B and the lateral surface of the upper end portion AR1 of the active region AR. The second capping insulating layer 134B may be disposed between the third portions BC3 of the buried contacts BC disposed on the lateral surfaces of the adjacent active regions AR, and the second capping insulating layer 134B may separate the third portions BC3 of the buried contacts BC. Therefore, the second capping insulating layer 134B and the fence pattern FN may separate the adjacent buried contacts BC from each other.

As described, the capping insulating layer 134 further includes a second capping insulating layer 134B disposed on the first capping insulating layer 134A in addition to the first capping insulating layer 134A covered by or overlapped by the gate insulating layer 132, so when a fence pattern trench FNT is formed for forming a fence pattern FN disposed on the capping insulating layer 134, the depth of the fence pattern trench FNT in the third direction Z may be relatively less, compared to the case when there is no second capping insulating layer 134B. Therefore, when forming the fence pattern FN, generation of process errors may be reduced during the process for forming a fence pattern trench FNT and the process for filling the fence pattern trench FNT with an insulating layer.

The capping insulating layer 134 may include a second capping insulating layer 134B disposed on the first capping insulating layer 134A and having a relatively narrow width, and the level of the top surface of the upper end portion AR1 of the active region AR may be higher than the level of the first capping insulating layer 134A of the capping insulating layer 134 by the level difference DH so the lateral surface of the second capping insulating layer 134B may be spaced apart from the lateral surface of the upper end portion AR1 of the active region AR and may face each other in the second direction Y, and the third portion BC3 of the buried contact BC may be disposed between the lateral surface of the second capping insulating layer 134B and the lateral surface of the upper end portion AR1 of the active region AR spaced from each other and facing each other. Therefore, the contact area between the buried contact BC and the active region AR may increase, and accordingly stability of the contact may increase.

The capping insulating layer 134 may, for example, include at least one of silicon nitride (SiN), silicon oxynitride (SiON), silicon oxide (SiO₂), silicon carbonitride (SiCN), silicon oxycarbonitride (SiOCN), and/or combinations thereof. However, the position, shape, and material of the capping insulating layer 134 may not be limited thereto, and may be changed in many ways.

An insulating layer 640 may be disposed on the word line structure WLS, and the insulating layer 640 may have various types of contact holes for exposing the surface or inside of the substrate 100 together with the insulating structures. The insulating layer 640 may not be disposed between the word line structure WLS and the fence pattern FN.

The bit line BL may extend in the second direction Y and may cross the active region AR and the word line WL. The bit line BL may be disposed on the word line WL.

The bit line BL may be connected to the active region AR through the direct contact DC.

A direct contact trench DCT may be formed on the substrate 100, and a direct contact DC may be disposed in the direct contact trench DCT. The direct contact trench DCT may be disposed in the active region AR, and the direct contact DC may be connected to the active region AR. The direct contact DC may be directly connected to the active region AR. The direct contact DC may overlap the active region AR in the third direction Z.

The direct contact DC may include a conductive material. For example, the direct contact DC may include impurity-doped polysilicon or metal such as W, Mo, Au, Cu, Al, Ni, or Co.

The bit line BL may be disposed on the substrate 100 and the direct contact DC. The bit line BL may include a first conductive layer 151, a second conductive layer 153, and a third conductive layer 155 that are sequentially stacked.

The first conductive layer 151, the second conductive layer 153, and the third conductive layer 155 may include conductive materials. For example, the first conductive layer 151 may include impurity-doped polysilicon or metal such as W, Mo, Au, Cu, Al, Ni, or Co. For example, the second conductive layer 153 may include metal such as Ti or Ta and/or metal nitride such as TiN or TaN. For example, the third conductive layer 155 may include metal such as W, Mo, Au, Cu, Al, Ni, or Co. As the first conductive layer 151, the second conductive layer 153, and the third conductive layer 155 have different materials and areas, the first conductive layer 151, the second conductive layer 153, and the third conductive layer 155 may have different electrical resistance. For example, the first conductive layer 151 may have the highest electrical resistance, and the third conductive layer 155 may have the lowest electrical resistance. However, the structure, material, and electrical resistance of the conductive layers configuring the bit line BL may not be limited thereto.

The bit line BL may directly contact the direct contact DC. The first conductive layer 151 of the bit line BL may contact the lateral surface of the direct contact DC, and the second conductive layer 153 of the bit line BL may directly contact the upper surface of the direct contact DC. The direct contact DC may be disposed between the active region AR and the bit line BL, and may electrically connect the active region AR and the bit line BL. That is, the bit line BL may be connected to the active region AR through the direct contact DC.

From among the conductive layers configuring the bit line BL, the first conductive layer 151 and the direct contact DC may include the same material. For example, the first conductive layer 151 and the direct contact DC may include impurity-doped polysilicon. However, embodiments may not be limited thereto, and the first conductive layer 151 and the direct contact DC may include different materials.

A bit line capping layer 158 may be disposed on the bit line BL. The bit line BL and the bit line capping layer 158 may configure a bit line structure BLS. The bit line capping layer 158 may overlap the bit line BL and the direct contact DC in the third direction Z. The bit line BL and the direct contact DC may be patterned using the bit line capping layer 158 as a mask.

The bit line BL may have substantially the same planar shape as the bit line capping layer 158. The bit line capping layer 158 is shown to contact the third conductive layer 155 of the bit line BL, but is not limited thereto. Another layer may be further disposed between the bit line capping layer 158 and the third conductive layer 155 of the bit line BL.

The bit line capping layer 158 may include silicon nitride. However, the material of the bit line capping layer 158 may not be limited thereto.

A spacer structure 620 may be disposed on both sides of the bit line structure BLS. The spacer structure 620 may cover, overlap, or be on lateral surfaces of the bit line capping layer 158, the bit line BL, and the direct contact DC.

The spacer structure 620 may extend in the third direction Z along a lateral surface of the bit line structure BLS. At least a portion of the spacer structure 620 may be disposed in the direct contact trench DCT. The spacer structure 620 may be disposed on both sides of the direct contact DC in the direct contact trench DCT.

The spacer structure 620 may be a multilayer made of combinations of various types of insulating materials. The spacer structure 620 may include a first spacer 622, a second spacer 624, a third spacer 626, and a fourth spacer 628. However, the embodiment is not limited thereto, and the number and structure of the layers configuring the spacer structure 620 vary.

The spacer structure 620 may be a single layer. In some embodiments, the spacer structure 620 may have an air spacer structure surrounded by spacers and having an air space.

The first spacer 622 may cover, overlap, or be on the lateral surfaces of the bit line structure BLS and the direct contact DC. The first spacer 622 may cover, overlap, or be on the bottom surface and lateral surface of the direct contact trench DCT in the direct contact trench DCT.

The second spacer 624 may be disposed on the first spacer 622. The bottom surface and the lateral surface of the second spacer 624 may be surrounded by the first spacer 622. The second spacer 624 may be disposed in the direct contact trench DCT. The second spacer 624 may fill the direct contact trench DCT. The second spacer 624 may be disposed on both sides of the direct contact DC in the direct contact trench DCT.

The third spacer 626 may be disposed on the first spacer 622 and the second spacer 624. The third spacer 626 may overlap the first spacer 622 in the first direction X and may overlap the second spacer 624 in the third direction Z. The third spacer 626 may extend substantially in the third direction Z along the lateral surface of the first spacer 622. The third spacer 626 may extend in parallel to the first spacer 622. The bottom surface and the lateral surface of the third spacer 626 may be surrounded by the first spacer 622, the second spacer 624, and the fourth spacer 628.

The fourth spacer 628 may be disposed on the second spacer 624 and the third spacer 626. The fourth spacer 628 may overlap the second spacer 624 in the third direction Z and may overlap the third spacer 626 in the first direction X. The fourth spacer 628 may extend substantially in the third direction Z along the lateral surface of the third spacer 626. The fourth spacer 628 may extend in parallel to the first spacer 622 and the third spacer 626. The bottom surface and the lateral surface of the fourth spacer 628 may be surrounded by the second spacer 624 and the third spacer 626.

The spacer structure 620 may include an insulating material. The first spacer 622, the second spacer 624, the third spacer 626, and the fourth spacer 628 may include the same material. Alternatively, at least some of the first spacer 622, the second spacer 624, the third spacer 626, and the fourth spacer 628 may include different materials.

Each of the first spacer 622, the second spacer 624, the third spacer 626, and the fourth spacer 628 may include at least one of silicon nitride, silicon oxynitride, silicon oxide, silicon oxycarbide, silicon carbonitride, silicon oxycarbonitride, and/or combinations thereof. For example, the first spacer 622 and the third spacer 626 may include silicon oxide, and the second spacer 624 and the fourth spacer 628 may include silicon nitride. However, the embodiment is not limited thereto, and the material of the spacer structure 620 may not be limited thereto.

The insulating layer 640 may be disposed below the bit line BL. The insulating layer 640 may be disposed between the word line structure WLS and the bit line BL. The insulating layer 640 may be disposed between the bit line BL and the element separating layer 112.

The insulating layer 640 may have contact holes, and may not be disposed between the bit line BL in which the direct contact DC is disposed and the active region AR.

The insulating layer 640 may include a first insulating layer 642, a second insulating layer 644, and a third insulating layer 646 that are sequentially stacked.

At least some of the first insulating layer 642, the second insulating layer 644, and the third insulating layer 646 may have different widths in the first direction X. The second insulating layer 644 and the third insulating layer 646 may have substantially the same widths. The second insulating layer 644 and the third insulating layer 646 may have substantially the same widths as the bit line BL and the bit line capping layer 158. The first insulating layer 642 may have a different width from the second insulating layer 644 and the third insulating layer 646. The width of the first insulating layer 642 may be greater than the widths of the second insulating layer 644 and the third insulating layer 646. Therefore, the width of the first insulating layer 642 may be greater than the width of the bit line BL.

The insulating layer 640 may be covered by or overlapped by the spacer structure 620. For example, the upper surface of the first insulating layer 642 may be covered by or overlapped by the first spacer 622. The lateral surfaces of the second insulating layer 644 and the third insulating layer 646 may be covered by or overlapped by the first spacer 622.

The insulating layer 640 may include an insulating material. Each of the first insulating layer 642, the second insulating layer 644, and the third insulating layer 646 may include an insulating material. For example, the first insulating layer 642 may include silicon oxide. The second insulating layer 644 may include a material with different etch selectivity from the first insulating layer 642. For example, the second insulating layer 644 may include silicon nitride.

For example, the third insulating layer 646 may include silicon oxide or silicon nitride. However, the embodiment is not limited thereto, and the structure and material of the insulating layer 640 may vary.

As shown in FIG. 3, the buried contact BC may be disposed between the bit lines BL.

The semiconductor device 10 may include buried contacts BC. The buried contacts BC may be spaced apart from each other in the first direction X and the second direction Y. For example, the buried contacts BC may be spaced apart from each other in the second direction Y between the adjacent two bit lines BL. The buried contacts BC may be spaced apart from each other in the first direction X between the adjacent two word lines WL. However, the embodiment is not limited thereto, and the arrangement of the buried contacts BC may vary.

At least a portion of the buried contact BC may overlap the active region AR in the third direction Z, and another portion thereof may overlap the element separating layer 112 in the third direction Z. The buried contact BC may be electrically connected to the active region AR. The buried contact BC may directly contact the active region AR. At least a portion of the bottom surface and the lateral surface of the buried contact BC is surrounded by the active region AR.

The buried contact BC may include a first portion BC1 disposed between two adjacent fence patterns FN and having a substantially constant width W21 in the second direction Y, a second portion BC2 extending toward the active region AR from the first portion BC1 in the third direction Z and having a width W22 gradually increasing in the second direction Y approaching the active region AR, and a third portion BC3 extending toward the active region AR from the second portion BC2 in the third direction Z, disposed between the active region AR and the second capping insulating layer 134B, and disposed on the lateral surface of the upper end portion AR1 of the active region AR. The third portion BC3 may contact an upper surface of the first capping insulating layer 134A.

The second portion BC2 of the buried contact BC may contact the top surface of the upper end portion AR1 of the active region AR, and the third portion BC3 of the buried contact BC may contact the lateral surface of the upper end portion AR1 of the active region AR.

As described, the buried contact BC includes the second portion BC2 contacting the top surface of the upper end portion AR1 of the active region AR and the third portion BC3 contacting the lateral surface of the upper end portion AR1 of the active region AR, thereby increasing a contact area of the buried contact BC and the active region AR, and increasing stability of the contacts.

The buried contact BC may include a conductive material. For example, the buried contact BC may include impurity-doped polysilicon, and the embodiment is not limited thereto.

The spacer structure 620 may be disposed on both lateral surfaces of the buried contact BC. The spacer structure 620 may be disposed between the buried contact BC and the bit line BL. For example, one lateral surface of the buried contact BC may contact the fourth spacer 628 and the active region AR, and another lateral surface of the buried contact BC may contact the fourth spacer 628 and the second spacer 624. The bottom surface of the buried contact BC may contact the first spacer 622. However, the embodiment is not limited thereto, and a positional relationship between the buried contact BC and the spacer structure 620 may vary.

The upper surface of the buried contact BC may be disposed on a lower level than the upper surface of the bit line BL, and the bottom surface of the buried contact BC may be disposed on a higher level than the bottom surface of the direct contact DC. However, the embodiment is not limited thereto, and the positional relationship among the buried contact BC, the bit line BL, and the direct contact DC may vary.

The fence pattern FN may be disposed between the bit lines BL and between the buried contacts BC.

That is, the fence pattern FN may be disposed between the bit lines BL and spaced apart from each other in the first direction X. The fence pattern FN may also be disposed between the buried contact BC and spaced apart from each other in the second direction Y.

In an embodiment, the fence pattern FN may extend in the first direction X and may be disposed on the word line structure WLS. The width of the fence pattern FN in the second direction Y may be substantially equal to the width of the word line structure WLS in the second direction Y or may be less than the width of the word line structure WLS in the second direction Y. However, the embodiment is not limited thereto, and the planar shape of the fence pattern FN and the width of the fence pattern FN may vary.

The fence pattern FN may be disposed between the bit lines BL and between the buried contacts BC. That is, the fence pattern FN may overlap the capping insulating layer 134 in the third direction Z and may extend in the third direction Z between the bit lines BL and between the buried contact BC.

The lateral surface of the fence pattern FN may contact the buried contact BC, and the landing pad LP to be described. The lateral surface of the fence pattern FN may contact the first spacer 622 and the fourth spacer 628 disposed on an outermost portion of the spacer structure 620.

The bottom surface of the fence pattern FN may contact the upper portion of the second capping insulating layer 134B of the capping insulating layer 134, and the lateral surface of the fence pattern trench FNT spaced in the first direction X may contact the spacer structure 620, and the lateral surface of the fence pattern trench FNT spaced in the second direction Y may contact the buried contact BC.

At least a portion of the upper surface of the second capping insulating layer 134B may be recessed by the fence pattern FN. The bottom surface of the fence pattern FN may have a shape concavely sunken toward the bottom surface from the upper surface of the second capping insulating layer 134B.

At least a portion of the bottom surface of the fence pattern FN may be disposed on the lower level than the upper surface of the upper end portion AR1 of the active region AR. The bottom surface of the fence pattern FN may be disposed on the lower level than the bottom surface of the first insulating layer 642.

However, the lateral surface of the upper end portion AR1 of the active region AR disposed between the lateral surface of the second capping insulating layer 134B and the third portion BC3 of the buried contact BC may be disposed on the lower level than the bottom surface of the fence pattern FN.

The fence pattern FN may include, for example, at least one of silicon oxide, silicon nitride, silicon oxynitride, and/or combinations thereof, and the embodiment is not limited thereto.

The landing pad LP may be disposed on the buried contact BC. The semiconductor device 10 may include a plurality of landing pads LP. The landing pads LP may be spaced apart from each other in the first direction X and the second direction Y. The landing pads LP may be arranged in series in the first direction X. The landing pads LP may be arranged with a zigzag pattern in the second direction Y. For example, the landing pads LP may be alternately arranged on the right and left sides of the bit line BL. However, the embodiment is not limited thereto, and the arrangement of the landing pads LP may vary.

The landing pad LP may cover, overlap, or be on the upper surface of the buried contact BC and may overlap the buried contact BC in the third direction Z. At least a portion of the landing pad LP may overlap the spacer structure 620 in the third direction Z and may overlap the bit line BL in the third direction Z. The upper surface of the landing pad LP may be disposed on a higher level than the upper surface of the bit line capping layer 158. The spacer structure 620 may be disposed on both lateral surfaces of the landing pad LP. The spacer structure 620 may be disposed between the landing pad LP and the bit line BL and between the landing pad LP and the bit line capping layer 158. The landing pad LP may be electrically connected to the buried contact BC. The landing pad LP may directly contact the buried contact BC. The landing pad LP may be electrically connected to the active region AR through the buried contact BC.

The landing pad LP may include a metal silicide layer 171, a conductive barrier layer 173, and a conductive layer 175. The metal silicide layer 171 may be disposed on the buried contact BC, the conductive barrier layer 173 may be disposed on the metal silicide layer 171, and the conductive layer 175 may be disposed on the conductive barrier layer 173.

The metal silicide layer 171 may directly contact the buried contact BC. The metal silicide layer 171 may cover, overlap, or be on the upper surface of the buried contact BC. The upper surface of the buried contact BC may be concave, and the metal silicide layer 171 may have a convex shape along the upper surface of the buried contact BC. The spacer structure 620 may be disposed on both lateral surfaces of the metal silicide layer 171. For example, the metal silicide layer 171 may contact the fourth spacer 628.

The metal silicide layer 171 may include a metal silicide material such as cobalt silicide, nickel silicide, or manganese silicide. However, the embodiment is not limited thereto, and the shape and material of the metal silicide layer 171 may vary. In another embodiment, the metal silicide layer 171 may be omitted.

The conductive barrier layer 173 may be disposed between the metal silicide layer 171 and the conductive layer 175. The bottom surface of the conductive barrier layer 173 may contact the metal silicide layer 171. The spacer structure 620 may be disposed on both lateral surfaces of the conductive barrier layer 173. For example, the conductive barrier layer 173 may cover, overlap, or be on the upper surfaces of the fourth spacer 628, the third spacer 626, and the first spacer 622.

The conductive barrier layer 173 may contact the fourth spacer 628, the third spacer 626, and the first spacer 622.

The landing pad LP may contact the fence pattern FN. For example, the metal silicide layer 171 and the conductive barrier layer 173 may contact the lateral surface of the fence pattern FN. That is, the metal silicide layer 171 and the conductive barrier layer 173 may be disposed on the lateral surface of the fence pattern FN. However, the embodiment is not limited thereto, and the arrangement relationship of the conductive barrier layer 173 and the fence pattern FN may vary.

The conductive barrier layer 173 may include Ti, TiN, or combinations thereof.

However, the embodiment is not limited thereto, and the shape and material of the conductive barrier layer 173 may vary.

The bottom surface of the conductive layer 175 may contact the conductive barrier layer 173. At least a portion of the bottom surface and the lateral surface of the conductive layer 175 may be surrounded by the conductive barrier layer 173. The conductive barrier layer 173 may be disposed between the conductive layer 175 and the metal silicide layer 171. The conductive barrier layer 173 may be disposed between the conductive layer 175 and the spacer structure 620.

The conductive layer 175 may include metal, metal nitride, impurity-doped polysilicon, and/or combinations thereof. For example, the conductive layer 175 may include W. However, the embodiment is not limited thereto, and the shape and material of the conductive layer 175 may vary.

An insulating pattern 660 may be disposed between the landing pads LP. The insulating pattern 660 may fill the space between the landing pads LP. The landing pads LP may be separated from each other by the insulating pattern 660.

The insulating pattern 660 may be disposed on the fence pattern FN. The insulating pattern 660 may recess the fence pattern FN toward the bottom surface from the upper surface of the fence pattern FN. Hence, the insulating pattern 660 may protrude into the fence pattern FN.

In other words, the fence pattern FN may be sunken lower in the third direction Z by the insulating pattern 660.

The insulating pattern 660 may include silicon nitride, silicon oxynitride, silicon oxide, or combinations thereof. The insulating pattern 660 may be a single layer or a multilayer. For example, the insulating pattern 660 may include a first material layer and a second material layer that are stacked. The first material layer may include a silicon oxide or at least one low dielectric (low-k) material with a lower dielectric constant than the silicon oxide such as SiOCH or SiOC, and the second material layer may include silicon nitride or silicon oxynitride. However, the embodiment is not limited thereto, and the shape and material of the insulating pattern 660 may vary.

Although not shown, a capacitor structure may be disposed on the landing pad LP. The capacitor structure may include a first capacitor electrode, a second capacitor electrode, and a dielectric layer disposed between the first capacitor electrode and the second capacitor electrode. The first capacitor electrode may contact the landing pad LP and may be electrically connected to the landing pad LP. The capacitor structure may be electrically connected to the active region AR through the landing pad LP and the buried contact BC.

The semiconductor device 10 may include a plurality of capacitor structures. The first capacitor electrodes may be disposed on each of the landing pads LP, and the first capacitor electrodes may be spaced apart from each other. The same voltage may be applied to second capacitor electrodes of the capacitor structures, and the second capacitor electrodes may be integrally formed. Dielectric layers of the capacitor structures may be integrally formed.

According to the semiconductor device 10, the capping insulating layer 134 of the word line structure WLS may include a first capping insulating layer 134A and a second capping insulating layer 134B having different widths in the second direction Y, and the width Wi1 of the first capping insulating layer 134A may be greater than the width W12 of the second capping insulating layer 134B. The top surface of the upper end portion AR1 of the active region AR may have a higher level than the first capping insulating layer 134A of the capping insulating layer 134 by the level difference DH so the lateral surface of the second capping insulating layer 134B may be spaced apart from the lateral surface of the upper end portion AR1 of the active region AR in the second direction Y and may face each other, and the third portion BC3 of the buried contact BC may be disposed between the lateral surface of the second capping insulating layer 134B and the lateral surface of the upper end portion AR1 of the active region AR spaced from each other and facing each other. Therefore, the contact area between the buried contact BC and the active region AR may increase, and the stability of contacts may accordingly increase.

The capping insulating layer 134 further includes the second capping insulating layer 134B disposed on the first capping insulating layer 134A in addition to the first capping insulating layer 134A covered by or overlapped by the gate insulating layer 132 so when the fence pattern trench FNT is formed to form the fence pattern FN disposed on the capping insulating layer 134, a depth of the fence pattern trench FNT in the third direction Z that is a height direction may be relatively less compared to the case when there is no second capping insulating layer 134B. Therefore, when the fence pattern FN is formed, generation of processing errors may be reduced during the process for forming a fence pattern trench FNT and the process for filling the fence pattern trench FNT with an insulating layer.

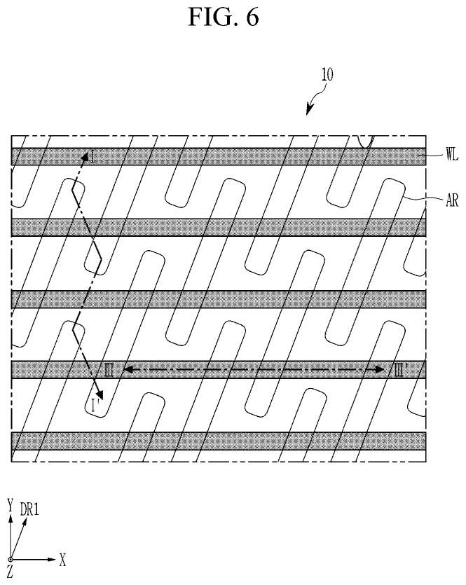

A method for manufacturing a semiconductor device according to an embodiment will now be described with reference to FIG. 6 to FIG. 25. The same components as the semiconductor device according to the embodiment described with reference to FIG. 1 to FIG. 5 will be described using the same reference numerals, and the repeated descriptions will be omitted or simplified.

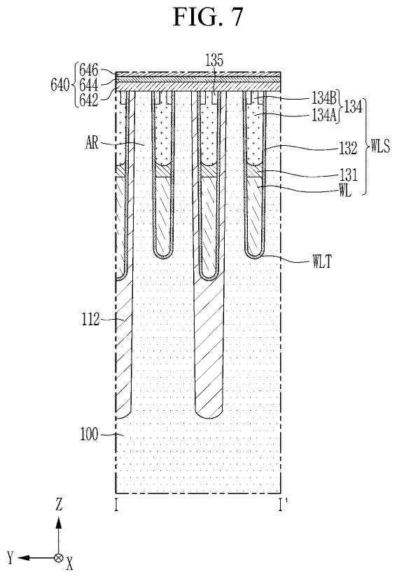

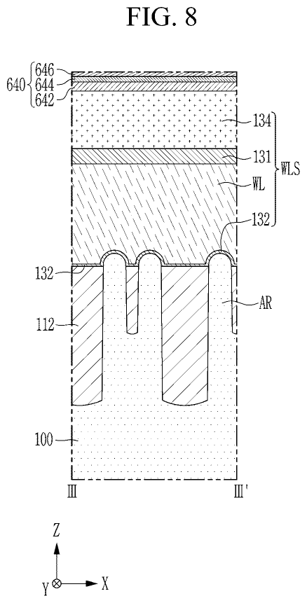

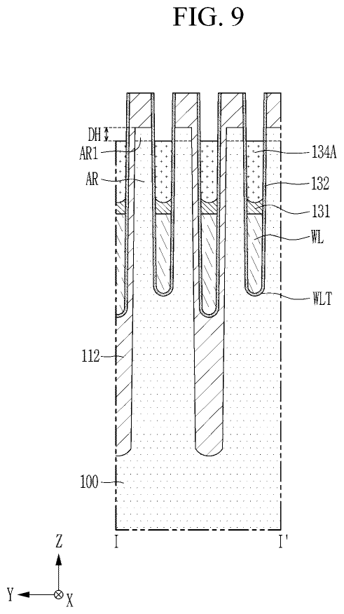

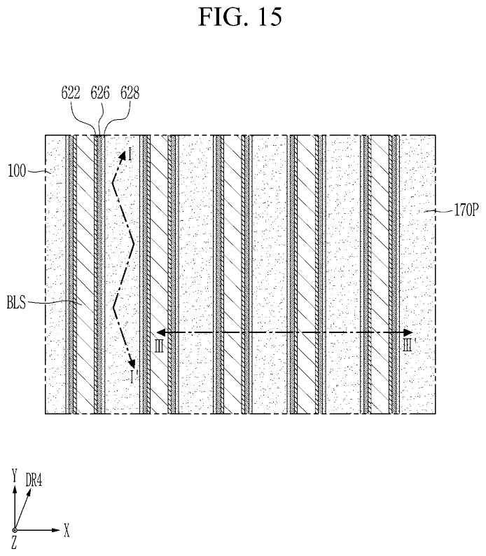

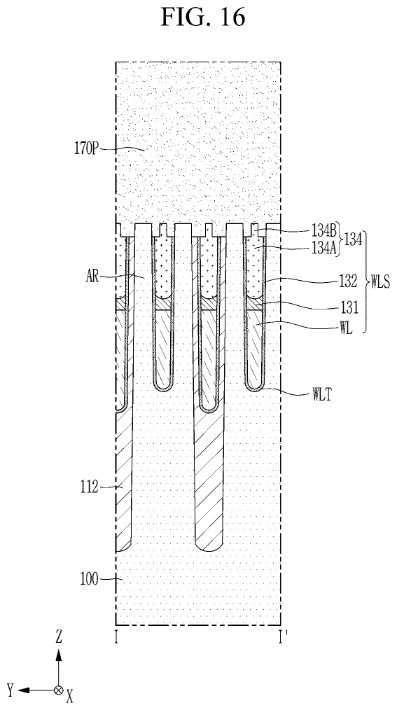

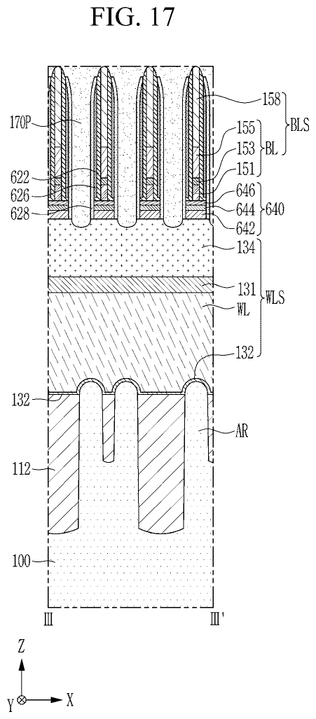

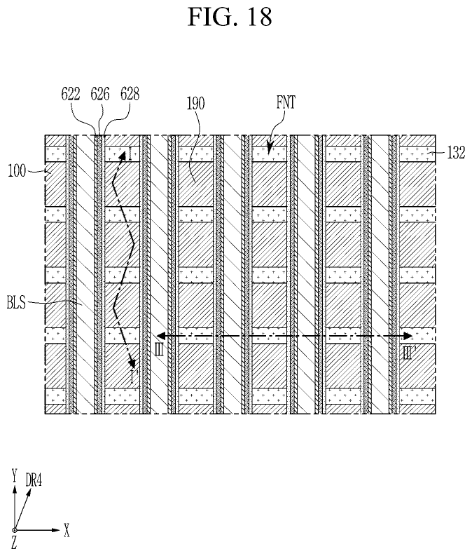

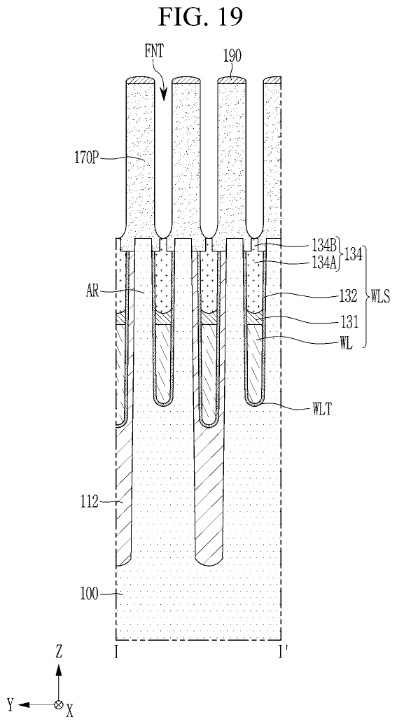

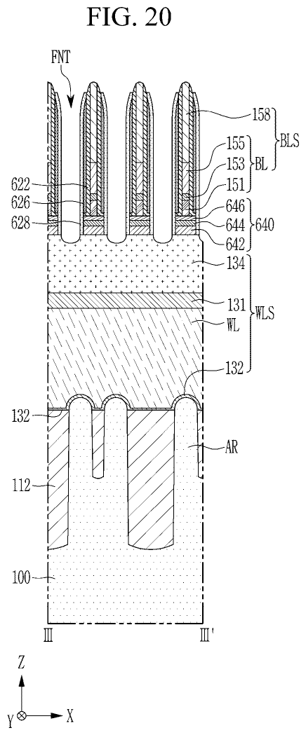

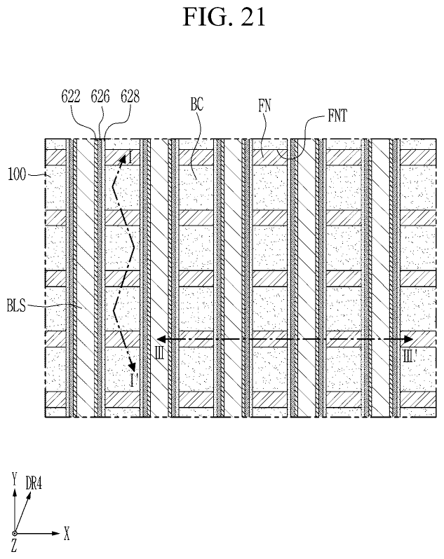

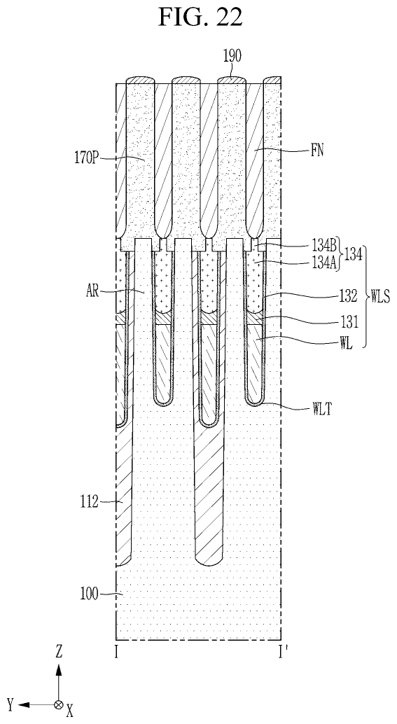

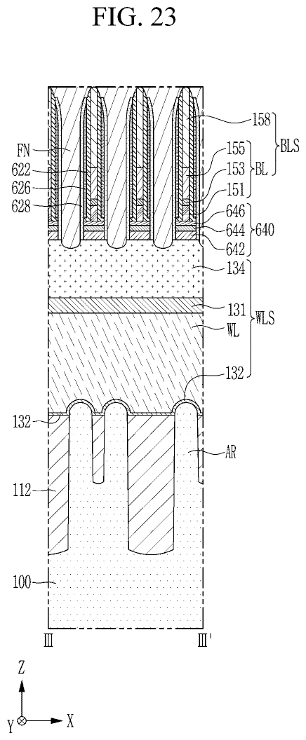

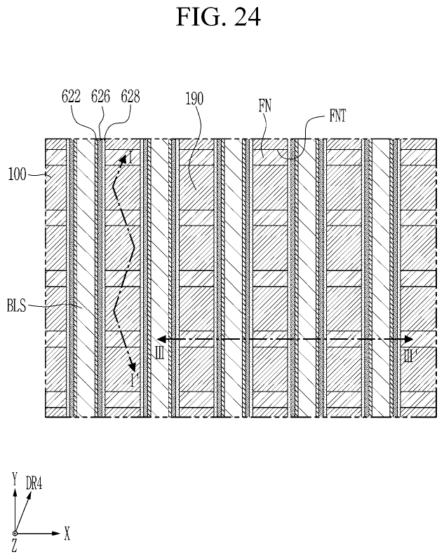

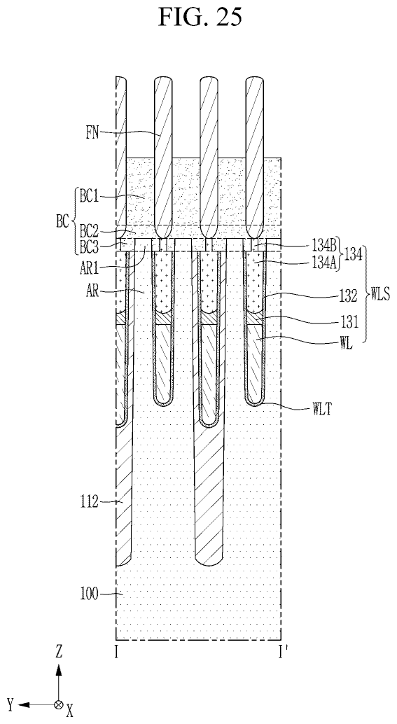

FIG. 6 to FIG. 25 show plan views and cross-sectional views of a method for manufacturing a semiconductor device according to an embodiment. In detail, FIG. 6 shows a layout or plan view in a predetermined process of a method for manufacturing a semiconductor device according to an embodiment, FIG. 7 shows a cross-sectional view with respect to a line I-I′ in a predetermined process of a method for manufacturing a semiconductor device of FIG. 6, and FIG. 8 shows a cross-sectional view with respect to a line III-III′ in a predetermined process of a method for manufacturing a semiconductor device of FIG. 6. FIG. 9 to FIG. 14 show cross-sectional views of a semiconductor device of FIG. 7 in processing order. FIG. 15, FIG. 18, FIG. 21, and FIG. 24 show layout views in a predetermined process of a method for manufacturing a semiconductor device according to an embodiment, FIG. 16, FIG. 19, FIG. 22, and FIG. 25 show cross-sectional views of a semiconductor device with respect to a line I-I′ in processing order in a predetermined process of a method for manufacturing a semiconductor device according to an embodiment, and FIG. 17, FIG. 20, and FIG. 23 show cross-sectional views of a semiconductor device with respect to a line III-III′ in processing order in a predetermined process of a method for manufacturing a semiconductor device according to an embodiment.

Hereinafter, a method for forming an element separating layer 112, a direct contact DC, and a bit line structure BLS will be simplified, and a method for forming a word line structure WLS, a buried contact BC, and a fence pattern FN will now be mainly described.

Referring to FIG. 6 to FIG. 8, the element separating layer 112, the word line structure WLS, and the insulating layer 640 may be formed on the substrate 100.

A trench for separating elements may be formed on the substrate 100, and the element separating layer 112 may be formed to fill the trench.

The word line trench WLT may be formed in the substrate 100, and the word line structure WLS may be formed in the word line trench WLT. The word line structure WLS may be buried in the substrate 100. A portion of the word line trench WLT may be disposed in the active region AR, and another portion thereof may be disposed in the element separating layer 112.

Among the word line structure WLS, the capping insulating layer 134 may include a first capping insulating layer 134A and a second capping insulating layer 134B with different widths in the second direction Y, and the width W11 of the first capping insulating layer 134A may be greater than the width W12 of the second capping insulating layer 134B.

The active region AR may include the upper end portion AR1 protruding further than the first capping insulating layer 134A in the third direction Z.

A dummy insulating layer 135 may be disposed between the upper end portion AR1 of the active region AR and the second capping insulating layer 134B, and a portion of the element separating layer 112 and a portion of the gate insulating layer 132 may be disposed between the upper end portion AR1 of the active region AR and the second capping insulating layer 134B.

The insulating layer 640 may be formed in the word line structure WLS.

A method for forming a word line structure WLS according to the method for manufacturing a semiconductor device according to an embodiment will now be described in detail with reference to FIG. 9 to FIG. 14.

Referring to FIG. 9, a trench for separating elements may be formed in the substrate 100, an element separating layer 112 may be formed to fill the trench, a word line trench WLT may be formed, a gate insulating layer 132 may be formed to be conformally disposed in the word line trench WLT, and a word line WL, a capping conductive layer 131, and a first capping insulating layer 134A of the capping insulating layer 134 may be formed on the gate insulating layer 132 in the word line trench WLT.

The first capping insulating layer 134A may have a lower level than the active region AR in the third direction Z, and the active region AR may include the upper end portion AR1 protruding further than the first capping insulating layer 134A in the third direction Z. The top surface of the upper end portion AR1 of the active region AR may have a higher level than the first capping insulating layer 134A of the capping insulating layer 134 in the third direction Z by the level difference DH.

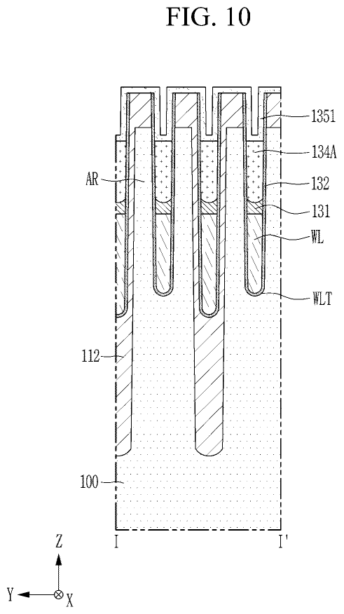

Referring to FIG. 10, a spacer insulating layer 1351 may be conformally disposed stacked on the element separating layer 112, the gate insulating layer 132, and the first capping insulating layer 134A of the capping insulating layer 134. The spacer insulating layer 1351 may include oxide.

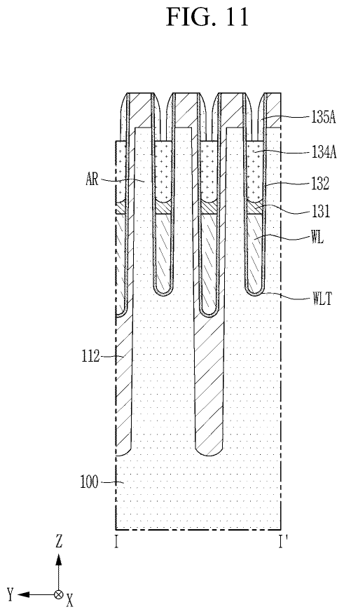

Referring to FIG. 11, the spacer insulating layer 1351 may be etched to form a dummy spacer layer 135A disposed on the lateral surfaces of the element separating layer 112 and the gate insulating layer 132.

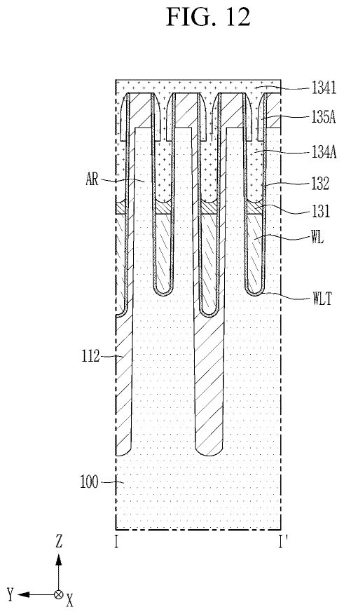

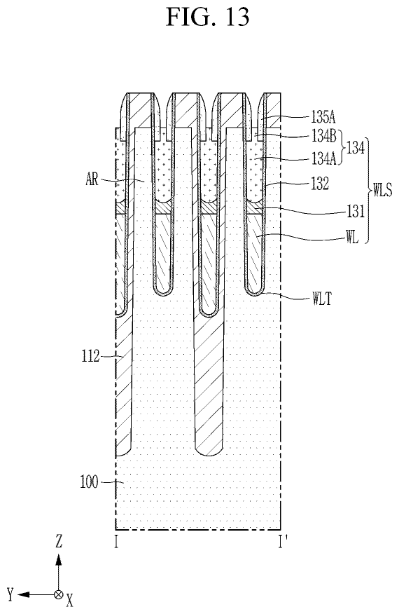

Referring to FIG. 12, a dummy capping layer 1341 may be stacked to fill the region between the dummy spacer layer 135A.

Referring to FIG. 13, the dummy capping layer 1341 may be stacked to a second capping insulating layer 134B disposed between the dummy spacer layer 135A.

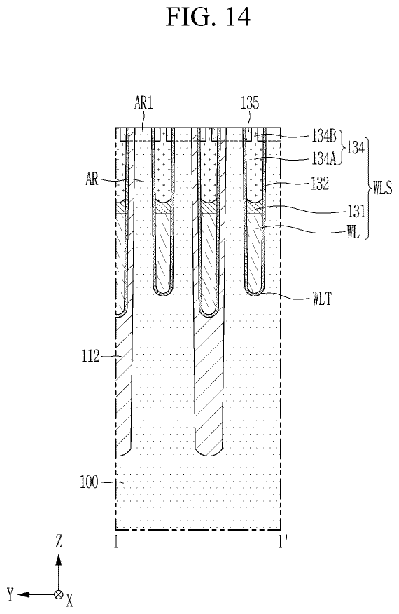

Referring to FIG. 14, portions of the element separating layer 112, the gate insulating layer 132, and the dummy spacer layer 135A disposed in the active region AR may be removed.

By this, the capping insulating layer 134 including the first capping insulating layer 134A and the second capping insulating layer 134B with different widths may be formed.

The dummy insulating layer 135 may be disposed between the second capping insulating layer 134B and the gate insulating layer 132.

The dummy insulating layer 135 disposed between the upper end portion AR1 of the active region AR and the second capping insulating layer 134B, a portion of the element separating layer 112, and a portion of the gate insulating layer 132 may be etched and removed together with the insulating layer 640 when various types of contact holes for exposing the surface or the inside of the substrate 100 are formed in the insulating layer 640 disposed in the word line structure WLS.

Referring to FIG. 15 to FIG. 17 together with FIG. 3, the direct contact (see DC of FIG. 3) for connecting the active region AR and the bit line BL of the substrate 100 may be formed, and the bit line BL including the first conductive layer 151, the second conductive layer 153, and the third conductive layer 155 that are sequentially stacked on the substrate 100 and the direct contact DC may be formed.

Here, various types of contact holes for exposing the surface or the inside of the substrate 100 may be formed in the insulating layer 640, and further the dummy insulating layer 135, a portion of the element separating layer 112, and a portion of the gate insulating layer 132, disposed between the upper end portion AR1 of the active region AR and the second capping insulating layer 134B may be removed together.

A spacer structure 620 extending substantially in the third direction Z along the lateral surface of the bit line structure BLS and including a first spacer 622, a second spacer 624, a third spacer 626, and a fourth spacer 628 may be formed, and a conductive material layer 170P may be formed on the substrate 100. The conductive material layer 170P may cover, overlap, or be on the upper surface of the capping insulating layer 134 and the upper surface of the active region AR, and the conductive material layer 170P may be formed between the bit line structures BLS spaced apart from each other in the first direction X. The conductive material layer 170P may extend in the second direction Y between the bit line structures BLS and may have a linear shape in a plan view. That is, the conductive material layer 170P may extend in the second direction Y in parallel to the bit line structure BLS in a plan view.

The conductive material layer 170P may directly contact the lateral surface of the spacer structure 620. For example, the conductive material layer 170P may directly contact the first spacer 622 and the fourth spacer 628. The upper surface of the conductive material layer 170P may be disposed on substantially the same level as the upper surface of the bit line capping layer 158.

The bottom surface of the conductive material layer 170P formed between the bit line structures BLS may directly contact the upper surface of the capping insulating layer 134.

The conductive material layer 170P may include a conductive material. For example, the conductive material layer 170P may include impurity-doped polysilicon, and without being limited thereto, the conductive material may vary.

Referring to FIG. 18 to FIG. 20, a hard mask pattern 190 may be formed on the conductive material layer 170P, and the conductive material layer 170P may be etched using the hard mask pattern 190 to thus form the fence pattern trench FNT.

A hard mask layer may be stacked on the conductive material layer 170P, and a hard mask pattern 190 may be formed by photolithographing and etching the hard mask layer.

The fence pattern trench FNT may overlap the word line structure WLS.

The conductive material layer 170P may configure the lateral surface of the fence pattern trench FNT, and the upper surface of the second capping insulating layer 134B may configure a portion of the bottom surface of the fence pattern trench FNT.

The conductive material layer 170P may exist in plurality. Each of the plurality of conductive material layers 170P with a linear shape in a plan view may be separated from each other by the second capping insulating layer 134B and the fence pattern trench FNT. The fence pattern trench FNT may be formed between the bit lines BL and between the buried contacts BC.

The conductive material layer 170P disposed between the bit line structures BLS may be etched using the bit line capping layer 158 and the spacer structure 620 disposed on both lateral surfaces of the bit line structure BLS as etching masks. Hence, the fence pattern trench FNT may be formed in the bit line structures BLS. The spacer structure 620 and the insulating layer 640 may configure the lateral surface of the fence pattern trench FNT, and the upper surface of the capping insulating layer 134 may configure the bottom surface of the fence pattern trench FNT.

As the conductive material layer 170P is etched, the upper surface of the bit line structure BLS may be exposed.

As the capping insulating layer 134 is over-etched to prevent the conductive material layer 170P from remaining on the capping insulating layer 134 during the process for etching the conductive material layer 170P using the hard mask pattern 190, the bit line capping layer 158, and the spacer structure 620, the capping insulating layer 134 may be recessed toward the bottom surface from the upper surface.

Hence, the upper surface of the capping insulating layer 134 configuring the bottom surface of the fence pattern trench FNT may include a curved surface. However, the embodiment is not limited thereto, and the shape of the bottom surface of the fence pattern trench FNT may vary. For example, the bottom surface of the fence pattern trench FNT may be recessed toward the capping insulating layer 134, in a quadrangular shape or a shape of which the width is reduced in accordance with a distance to the substrate 100. Hence, the shape of the bottom surface of the fence pattern FN may vary.

The capping insulating layer 134 may further include a second capping insulating layer 134B disposed on the first capping insulating layer 134A, and the bottom surface of the fence pattern trench FNT may contact the top surface of the second capping insulating layer 134B. Therefore, the depth of the fence pattern trench FNT may be relatively less in the third direction Z that is the height direction, compared to the case when there is no second capping insulating layer 134B. Therefore, the generation of process errors may be reduced during the process for forming a fence pattern trench FNT may be reduced.

Referring to FIG. 21 to FIG. 23, the fence pattern FN may be formed in the fence pattern trench FNT.

The lateral surface of the fence pattern FN may contact the conductive material layer 170P, and the bottom surface of the fence pattern FN may contact the capping insulating layer 134. The lateral surface of the fence pattern FN may contact the spacer structure 620.

The capping insulating layer 134 may further include the second capping insulating layer 134B disposed on the first capping insulating layer 134A, and the bottom surface of the fence pattern FN may contact the top surface of the second capping insulating layer 134B. Therefore, the depth of the fence pattern FN may be relatively less in the third direction Z that is the height direction, compared to the case when there is no second capping insulating layer 134B.

Therefore, the generation of process errors may be reduced during the process for filling the fence pattern trench FNT with the insulating layer and forming the fence pattern FN.

Referring to FIG. 24 and FIG. 25, the hard mask pattern 190 may be removed and the conductive material layer 170P may be patterned to form the buried contact BC. The buried contact BC may be formed by etching a portion of the conductive material layer 170P disposed between the fence pattern FN by use of the fence pattern FN as a mask.

The remaining conductive material layer 170P may be the buried contact BC by etching a portion of the conductive material layer 170P.

The buried contact BC may include a first portion BC1 disposed between the two adjacent fence patterns FN and having a substantially constant width W21 in the second direction Y, a second portion BC2 extending toward the active region AR from the first portion BC1 in the third direction Z and having a width W22 gradually increasing in the second direction Y as approaching to the active region AR, and a third portion BC3 extending toward the active region AR from the second portion BC2 in the third direction Z, disposed between the active region AR and the second capping insulating layer 134B, and disposed on the lateral surface of the upper end portion AR1 of the active region AR.

The capping insulating layer 134 may include a second capping insulating layer 134B disposed on the first capping insulating layer 134A and having a relatively narrow width, and the top surface of the upper end portion AR1 of the active region AR may have a higher level than the first capping insulating layer 134A of the capping insulating layer 134 by the level difference DH so the lateral surface of the second capping insulating layer 134B and the lateral surface of the upper end portion AR1 of the active region AR may be spaced apart from each other and may face each other in the second direction Y, and the third portion BC3 of the buried contact BC may be disposed between the lateral surface of the second capping insulating layer 134B and the lateral surface of the upper end portion AR1 of the active region AR spaced apart from each other and facing each other. Therefore, the contact area between the buried contact BC and the active region AR may increase and the stability of contact may increase.

During the process for using the fence pattern FN as a mask, and etching a portion of the conductive material layer 170P disposed between the fence pattern FN to form the buried contact BC, a portion of the upper region of the fence pattern FN is removed together, and the upper surface of the fence pattern FN may have a curved shape. However, the embodiment is not limited thereto, and the shape of the upper surface of the fence pattern FN may vary.

The landing pad LP connected to the buried contact BC may be formed, the insulating pattern 660 for separating the landing pad LP may be formed, and the semiconductor device 10 shown in FIG. 1 to FIG. 4 may be formed. Although not shown, the capacitor structure may be further formed on the landing pad LP.

According to the method for manufacturing a semiconductor device 10 according to an embodiment, when forming the word line structure WLS, the second capping insulating layer 134B preventing a complicated manufacturing process and having the width W12 that is narrower than the width W11 of the first capping insulating layer 134A in the second direction Y may be formed on the first capping insulating layer 134A by using the dummy spacer layer 135A.

Therefore, when the fence pattern trench FNT is formed to form the fence pattern FN disposed on the capping insulating layer 134, the depth of the fence pattern trench FNT may be relatively less in the third direction Z that is the height direction, compared to the case when there is no second capping insulating layer 134B. Therefore, when forming the fence pattern FN, the generation of process errors may be reduced during the process for forming the fence pattern trench FNT and the process for filling the fence pattern trench FNT with the insulating layer.

Further, the top surface of the upper end portion AR1 of the active region AR may have a higher level than the first capping insulating layer 134A of the capping insulating layer 134 by the level difference DH, and the 134B second capping insulating layer 134B disposed on the lateral surface of the upper end portion AR1 of the active region AR is formed on the first capping insulating layer 134A using the dummy spacer layer 135A so that the lateral surface of the second capping insulating layer 134B and the lateral surface of the upper end portion AR1 of the active region AR may be spaced apart from each other and may face each other in the second direction Y, and the third portion BC3 of the buried contact BC may be disposed between the lateral surface of the second capping insulating layer 134B and the lateral surface of the upper end portion AR1 of the active region AR spaced apart from each other and facing each other.

Therefore, the contact area between the buried contact BC and the active region AR may increase, and the stability of contact may increase.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor device comprising:
a substrate comprising an active region;
a word line on the active region and extending in a first direction that is parallel to the substrate;
a capping insulating layer on the word line;
a bit line overlapping the active region in the first direction and extending in a second direction intersecting the first direction;
a buried contact electrically connected to the active region;
a direct contact electrically connecting the active region and the bit line; and
a landing pad electrically connected to the buried contact,
wherein the capping insulating layer comprises a first capping insulating layer and a second capping insulating layer having different widths in the second direction,
wherein the second capping insulating layer is on the first capping insulating layer, and
wherein the buried contact is on side surfaces of the second capping insulating layer.

2. The semiconductor device of claim 1, wherein a width of the first capping insulating layer is greater than a width of the second capping insulating layer in the second direction.

3. The semiconductor device of claim 2, further comprising:
a fence pattern on the capping insulating layer,
wherein the second capping insulating layer and the fence pattern extend into the buried contact.

4. The semiconductor device of claim 3, wherein a bottom surface of the fence pattern contacts the second capping insulating layer.

5. The semiconductor device of claim 3, wherein the buried contact comprises a first portion on a lateral surface of the fence pattern and having a substantially constant width in the second direction,
wherein the buried contact further comprises a second portion extending toward the active region from the first portion and having a width in the second direction gradually increasing approaching the active region, and
wherein the buried contact further comprises a third portion extending from the second portion and on a lateral surface of the active region.

6. The semiconductor device of claim 5, wherein the active region comprises an upper end portion further from the substrate in a third direction perpendicular to the first direction and the second direction than the first capping insulating layer, and
wherein the third portion of the buried contact is on a lateral surface of the upper end portion of the active region.

7. The semiconductor device of claim 6, wherein the upper end portion of the active region and the second capping insulating layer are spaced apart from each other in the second direction.

8. The semiconductor device of claim 1, wherein the buried contact comprises a first portion having a substantially constant width in the second direction,
wherein the buried contact further comprises a second portion extending toward the active region from the first portion and having a width in the second direction gradually increasing approaching the active region, and
wherein the buried contact further comprises a third portion extending from the second portion and on a lateral surface of the active region.

9. The semiconductor device of claim 8, wherein the active region comprises an upper end portion further from the substrate in a third direction perpendicular to the first direction and the second direction than the first capping insulating layer, and
wherein the third portion of the buried contact is on a lateral surface of the upper end portion of the active region.

10. The semiconductor device of claim 9, wherein the upper end portion of the active region and the second capping insulating layer are spaced apart from each other in the second direction.

11. A semiconductor device comprising:
a substrate comprising an active region;
a word line on the active region;
a capping insulating layer on the word line; and
a buried contact on the active region,
wherein the capping insulating layer comprises a second capping insulating layer on a first capping insulating layer,
wherein the first capping insulating layer and the second capping insulating layer have different widths, and
wherein an upper portion of the active region and the second capping insulating layer are spaced apart from each other with the buried contact therebetween.

12. The semiconductor device of claim 11, wherein a width of the first capping insulating layer is greater than a width of the second capping insulating layer in a direction parallel to the substrate.

13. The semiconductor device of claim 11, wherein a portion of the buried contact has a width in a direction parallel to the substrate that increases closer to the substrate.

14. The semiconductor device of claim 11, wherein the buried contact directly contacts an upper surface of the first capping insulating layer.

15. The semiconductor device of claim 11, further comprising:
a capping conductive layer between the word line and the first capping insulating layer.

16. The semiconductor device of claim 11, further comprising:
a gate insulating layer between the word line and the active region and between the capping insulating layer and the active region.

17. The semiconductor device of claim 16, wherein the gate insulating layer directly contacts the first capping insulating layer and is spaced apart from the second capping insulating layer.

18. The semiconductor device of claim 11, further comprising:
a fence pattern on the second capping insulating layer and extending into the buried contact.

19. The semiconductor device of claim 18, wherein the fence pattern directly contacts the second capping insulating layer.

20. The semiconductor device of claim 11, further comprising:
a bit line overlapping the active region in a direction parallel to the substrate; and
a direct contact electrically connecting the active region and the bit line.
